(19) United States
(12) Patent Application Publication
(10) Pub. No.: US 2004/0266192 A1
(43) Pub. Date: Dec. 30, 2004

(54) Application of heated slurry for CMP

(75) Inventors: Gregory C. Lee, Belmont, CA (US); Cangshan Xu, Fremont, CA (US); Eugene Zhao, San Jose, CA (US); Jingang Yi, Albany, CA (US)

Correspondence Address: MARTINE & PENILLA, LLP, 710 LAKEWAY DRIVE, SUITE 170, SUNNYVALE, CA, 94085, US

(73) Assignee: LAM RESEARCH CORPORATION, FREMONT, CA

(21) Appl. No.: 10/611,137

(22) Filed: Jun. 30, 2003

(51) Int. Cl. H01L 21/302; H01L 21/461

(52) U.S. Cl. 438/691

(57) ABSTRACT

A method for processing a wafer using a chemical mechanical planarization (CMP) apparatus is provided. The method includes providing a wafer to be processed and heating a slurry to be applied to a polishing pad of the CMP apparatus. The method further includes applying the heated slurry to the polishing pad, and polishing the wafer using the heated slurry. The method also includes stopping the heating of the slurry for a subsequent wafer to be processed.

### BACKGROUND OF THE INVENTION

The present invention relates to chemical mechanical planarization (CMP) techniques and, more particularly, to a method for preheating a CMP apparatus before wafer polishing.

In the fabrication of semiconductor devices, there is a need to perform chemical mechanical planarization (CMP) operations. Typically, integrated circuit devices are in the form of multi-level structures. At the substrate level, transistor devices having diffusion regions are formed. In subsequent levels, interconnect metallization lines are patterned and electrically connected to the transistor devices to define the desired functional device. As is well known, patterned conductive layers are insulated from other conductive layers by dielectric materials, such as silicon dioxide. As more metallization levels and associated dielectric layers are formed, the need to planarize the dielectric material grows. Without planarization, fabrication of further metallization layers becomes substantially more difficult due to the variations in the surface topography. In other applications, metallization line patterns are formed in the dielectric material, and then, metal CMP operations are performed to remove excess material.

A chemical mechanical planarization (CMP) system is typically utilized to polish a wafer as described above. A CMP system typically includes system components for handling and polishing the surface of a wafer. Such components can be, for example, an orbital polishing pad, or a linear belt polishing pad. The pad itself is typically made of a polyurethane material or polyurethane in conjunction with other materials such as, for example a stainless steel belt. In operation, the belt pad is put in motion and then a slurry material is applied and spread over the surface of the belt pad. Once the belt pad having slurry on it is moving at a desired rate, the wafer is lowered onto the surface of the belt pad. In this manner, wafer surface that is desired to be planarized is substantially smoothed, much like sandpaper may be used to sand wood. The wafer may then be cleaned in a wafer cleaning system.

FIG. 1 shows a linear polishing apparatus 10 which is typically utilized in a CMP system. The linear polishing apparatus 10 polishes away materials on a surface of a semiconductor wafer 16. The material being removed may be a substrate material of the wafer 16 or one or more layers formed on the wafer 16. Such a layer typically includes one or more of any type of material formed or present during a CMP process such as, for example, dielectric materials, silicon nitride, metals (e.g., aluminum and copper), metal alloys, semiconductor materials, etc. Typically, CMP may be utilized to polish the one or more of the layers on the wafer 16 to planarize a surface layer of the wafer 16.

The linear polishing apparatus 10 utilizes a polishing belt 12, which moves linearly in respect to the surface of the wafer 16. The belt 12 is a continuous belt rotating about rollers 20. The rollers are typically driven by a motor so that the rotational motion of the rollers 20 causes the polishing belt 12 to be driven in a linear motion 22 with respect to the wafer 16.

The wafer 16 is held by a polishing head 18. The wafer 16 is typically held in position by mechanical retaining ring and/or by vacuum. The polishing head 18 positions the wafer atop the polishing belt 12 and moves the wafer 16 down to the polishing belt 12. The polishing head 18 applies the wafer 16 to the polishing belt 12 with pressure so that the surface of the wafer 16 is polished by a surface of the polishing belt 12.

Typically, before production is started, quality testing is conducted in each fabrication location before wafer production commences. This is often done because the state of the CMP tools is not in a production mode for the first several wafer polishing processes. Belt temperature and distribution of the slurry are different when the tools are coming out of initial state (wet-idle) as compared to the steady state achieved during stable production. Some testing results have shown that the removal rate (RR) and within-wafer non-uniformity (WIWNU) for the first few wafers are quite different from the steady-state values.

Therefore, multiple “dummy” wafers are typically run through the system so the temperature of the CMP system can be normalized to a steady state which in turn can stabilize the polishing rate of the wafer during the wafer processing operation. Because wafer polishing heats up the system due to the friction generated between the polishing pad and the wafer, the temperature of the polishing system generally increases from the starting temperature. Consequently, the polishing rates of the first wafer is generally quite different from the polishing rates of the fifth or later wafer. Therefore, the polishing of the “dummy” wafer increases the temperature of the polishing system until the temperature becomes stabilized after which production wafers may be processed. Unfortunately, this has the downside of wasting time and wafers. In addition, the polishing rate of the first wafer may be what is desired due to lack of distribution of the slurry on the polishing pad.

Therefore, there is a need for an apparatus that overcomes the problems of the prior art by having a CMP apparatus and method that can fully prepare the CMP apparatus for wafer polishing before the processing of the first wafer.

### SUMMARY OF THE INVENTION

Broadly speaking, the present invention fills this need by enabling the preheating of the CMP system to eliminate use of dummy wafers in a planarization/polishing operation. It should be appreciated that the present invention can be implemented in numerous ways, including as a process, an apparatus, a system, a device or a method. Several inventive embodiments of the present invention are described below.

In one embodiment, a method for processing a wafer using a chemical mechanical planarization (CMP) apparatus is provided. The method includes providing a wafer to be processed and heating a slurry to be applied to a polishing pad of the CMP apparatus. The method further includes applying the heated slurry to the polishing pad, and polishing the wafer using the heated slurry. The method also includes stopping the heating of the slurry for a subsequent wafer to be processed.

In another embodiment, a method for processing a wafer using a chemical mechanical planarization (CMP) apparatus is provided which includes providing a wafer to be processed and heating a slurry to be applied to a polishing pad of the CMP apparatus to a temperature between 70 F. and 100 F. The method also includes applying the heated slurry to the polishing pad and distributing the heated slurry evenly on the polishing pad. The method further includes polishing the wafer using the heated slurry and stopping the heating of the slurry for a subsequent wafer processing. When a polishing irregularity occurs, the method additionally includes stopping the polishing, lowering a temperature of the CMP apparatus to a starting state temperature, and preheating the CMP apparatus again.

In yet another embodiment, a computer readable medium including program instructions for implementing a method for processing a wafer using a chemical mechanical planarization (CMP) apparatus is provided. The computer medium includes program instructions for providing a wafer to be processed, and program instructions for heating a slurry to be applied to a polishing pad of the CMP apparatus, and program instructions for applying the heated slurry to the polishing pad. The computer readable medium also includes program instructions for polishing the wafer using the heated slurry, and program instructions for stopping the heating of the slurry for a subsequent wafer processing.

The advantages of the present invention are numerous. Most notably, by creating a method and apparatus for managing and controlling a chemical mechanical planarization environment when in a start-up or restart condition, wafer polishing and planarization may be significantly improved. Specifically, use heated slurry to preheat a CMP apparatus can accelerate the stabilization of the “warm-up” process when the apparatus is coming out of a wet-idle state or coming from a recovery state due to wafer polishing stoppage. The methods described herein can therefore effectively and efficiently improve the performance of the polishing of the first a few wafers when the CMP apparatus is coming out from wet-idle and consequently reduce or eliminate the use of dummy wafers. This can effectively reduce the cost-of-ownership (COO) significantly and increase wafer production efficiency.

It is to be understood that the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1 shows a linear polishing apparatus which is typically utilized in a CMP system.

FIG. 2 shows a chemical mechanical planarization (CMP) system with a slurry heater in accordance with one embodiment of the present invention.

FIG. 3 shows a timeline illustrating the slurry heat processes for the processing of an initial wafer at start-up or restart in accordance with one embodiment of the present invention.

FIG. 4 illustrates a modular CMP system in accordance with one embodiment of the present invention.

FIG. 5 is a flowchart defining a method for preheating the CMP system in accordance with one embodiment of the present invention.

FIG. 6 illustrates a flowchart defining a method of preheating the CMP system when an irregularity occurs in the polishing operation in accordance with one embodiment of the present invention.

### DETAILED DESCRIPTION OF THE INVENTION

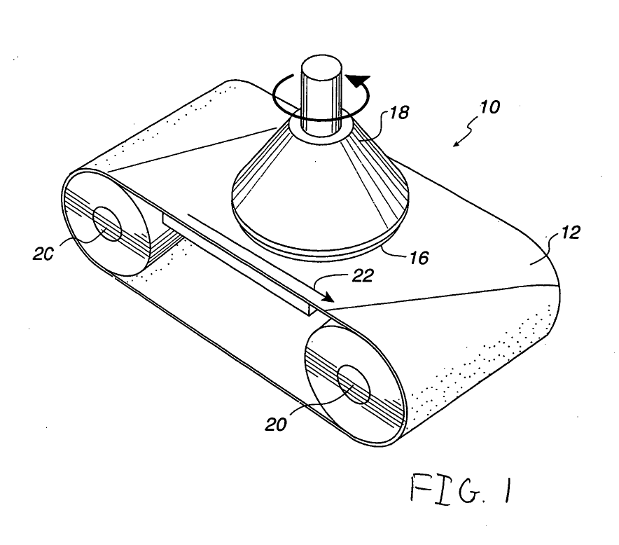

Several exemplary embodiments of the invention will now be described in detail with reference to the accompanying drawings. FIG. 1 is discussed above in the “Background of the Invention” section.

In the following description, numerous specific details are set forth in order to provide a thorough understanding of the present invention. It will be understood, however, by one of ordinary skill in the art, that the present invention may be practiced without some or all of these specific details. In other instances, well known process operations have not been described in detail in order not to unnecessarily obscure the present invention.

In general terms, the methods described herein may be used to achieve or restore the steady-state polishing rate in a short time with heated slurry which can be effectively eliminate the dummy wafers. This may be accomplished by building up the slurry/pad temperature as well as fully distributing slurry on the pad.

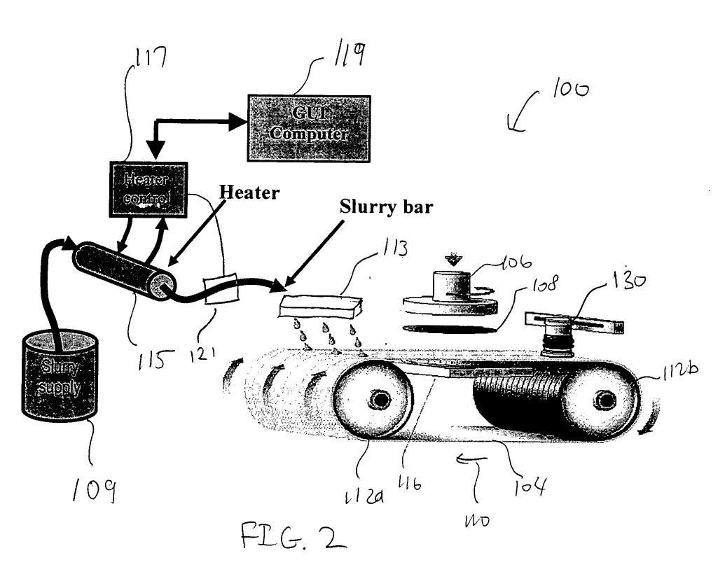

FIG. 2 shows a chemical mechanical planarization (CMP) system 100 with a slurry heating system in accordance with one embodiment of the present invention. A carrier head 106 may be used to secure and hold the wafer 108 in place during wafer polishing operations. A polishing belt 104 forms a continuous loop around rotating drums 112a and 112b. It should be appreciated that the polishing belt 104 as used herein may be any suitable type of structure such as, for example, a single layer polishing pad, a polishing pad supported by a stainless steel layer, a multilayer polishing structure (e.g., a polishing pad over a cushioning layer which is in turn over a stainless steel layer). It should also be appreciated that the principles described herein also apply to non-belt CMP devices, e.g., rotary devices. The polishing belt 104, in one embodiment, is a single layer polyurethane polishing pad utilized in linear CMP systems. In one exemplary embodiment, the polishing belt 104 generally rotates in a direction indicated by a direction 110 at a speed of about 400 feet per minute. Although, this speed does vary depending upon the specific CMP operation.

As the belt 104 rotates, polishing slurry may be applied and spread over the surface of the polishing belt 104. In one embodiment, a slurry dispenser 113 may be configured to apply heated slurry to the polishing belt 104. In a preferable embodiment, a polishing pad conditioner 130 may move back and forth from one edge of the polishing belt 104 to the other to evenly distribute the heated slurry on a polishing surface of the polishing belt 104. It should be appreciated that any suitable type of polishing pad conditioner 130 may be used and configured in any suitable fashion to enable the even distribution of the heated slurry over the polishing pad. In another embodiment, the slurry dispenser 113 may be configured to evenly distribute heated slurry to the polishing pad by, for example, zero downforce carrier head touchdown on the polishing pad. In one embodiment, after the heated slurry has been applied to the polishing pad and the CMP system 100 has been preheated, the carrier head 106 may then be used to lower the wafer 108 onto the surface of the rotating polishing belt 104. A platen 116 may support the polishing belt 104 during the polishing process. The platen 116 may utilize any suitable type of bearing such as an air bearing. In this manner, the surface of the wafer 108 that is desired to be planarized is substantially smoothed in an even manner.

When subsequent wafers after the first production wafer is processed, the heat being applied to the slurry is turned off so fabrication room temperature slurry is utilized. The heat may be turned off because the generated by the polishing operation is enough to keep the temperature of the apparatus at a steady state. In another embodiment, when a polishing shutdown occurs in a wafer processing module, when the polishing system is restarted, the first wafer processed during the restart is polished by using the heated slurry to preheat the system before wafer production is actually resumed.

In one embodiment, the CMP system 100 includes a slurry heater 115 to heat slurry to be dispensed from the slurry dispenser 113. As the slurry travels from the slurry heater 115 to the slurry dispenser 113, the temperature of the slurry is detected by a heat detector 121. It should be appreciated that the heat detector 121 may be any suitable type of heat detector that can determine a temperature of the slurry and/or polishing pad such as, for example, an IR heat detector. The heated slurry is then is applied to a top surface of the polishing belt 104. The heat detector 121 can determine the temperature of the slurry and relay the temperature information to a heater controller and monitor 117. In one embodiment, a desired temperature for the slurry may be set in a graphical-user-interface (GUI) computer 119 which can set (through, for example, software settings) the heater controller and monitor 117 to manage the attainment or maintenance of the set slurry temperature. It should be appreciated that the heater controller and monitor 117 may be any type of apparatus with logic and/or software that may process temperature input from the heat detector 121 and control the heating of the process environment. Therefore, by a feedback loop, a set temperature for the slurry may be attained and/or maintained by the heater controller and monitor 121 through the regulation of slurry by a slurry heater 115 that feeds the slurry dispenser 113.

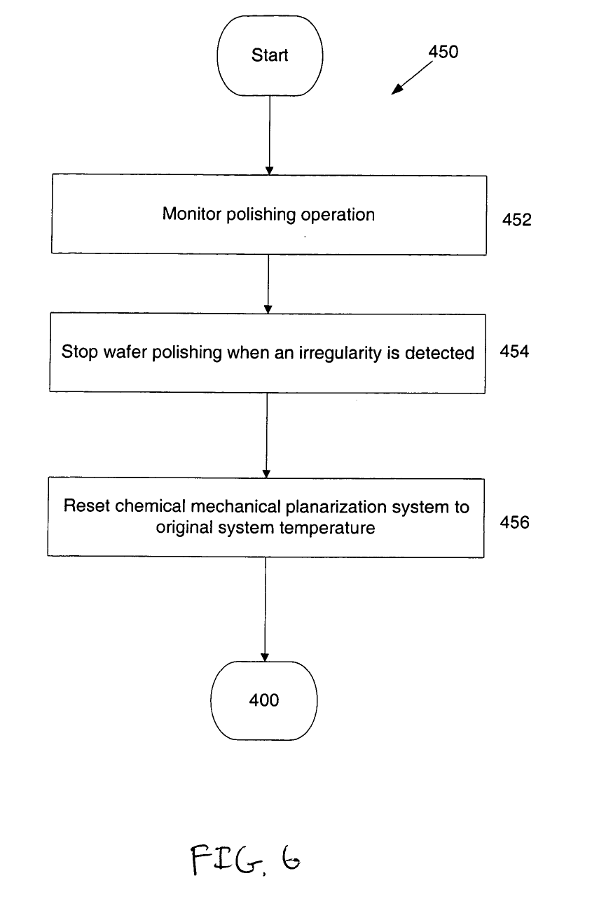

In one embodiment, unheated slurry has a temperature of 70 F. which is a typical temperature of a fabrication environment. The fabrication environment is typically a location such as a room where the wafer processing equipment is located. By increasing the temperature of the slurry, the system 100 may be preheated to a steady state polishing temperature for the polishing of a first wafer or for wafer polishing wafer to be polished after a restart following a polishing irregularity as described below in reference to FIG. 6. It should be appreciated that the steady state polishing temperature that the system 100 may reach through the polishing process can be varied with the speed of the polishing pad (increased speed may yield an increased steady state temperature due to the increased friction between the polishing pad and the wafer), with the downward force at which the wafer is pressed down onto the polishing pad (again due to the increased friction), etc. Therefore, by attaining a steady state temperature before the polishing of the first wafer, dummy wafers do not have to be utilized and consequently, wafer processing efficiency and output may be increased.

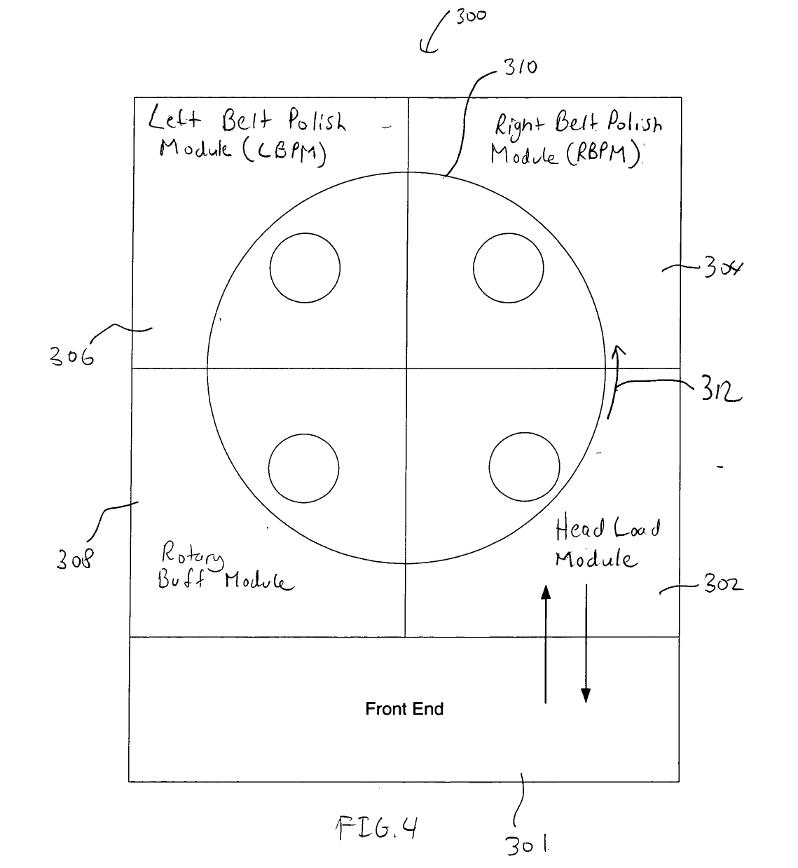

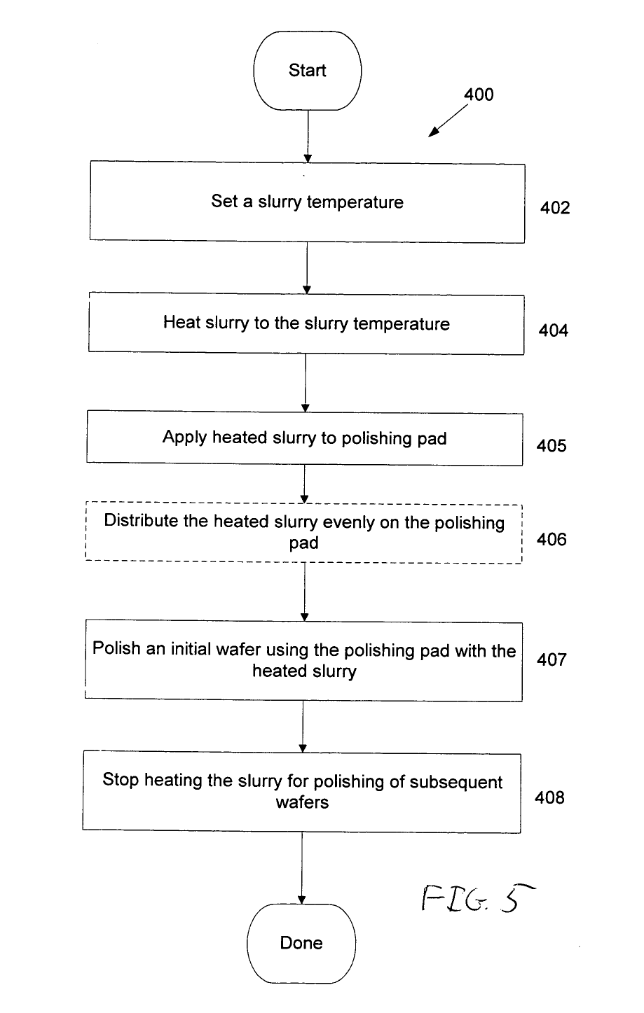

In an exemplary modular system (such as the one discussed in reference to FIG. 4), a heater may be installed on each polishing module and a temperature control unit can be added to regulate the slurry temperature. The slurry pipeline can go through the heater to the distribution slurry bar (nozzle). The heater controller can communicate with the GUI computer through, in one exemplary embodiment, an Ethernet standard interface. When heated slurry option is chosen for the process, the GUI computer can command the heater control unit to regulate the slurry temperature at a target setting-point. In one embodiment, heated slurry is applied the first wafer when the tool is coming out of wet-idle state (described in further detail below in reference to FIG. 5). In one embodiment, the heater is on when the slurry flow goes through the slurry pipeline in order to guarantee the safe operation. Hardware and software interlock design may implemented and unsafe operations such as fluid leaking, over-heated etc. can be prevented.

From the process viewpoint, the heated slurry process applied to the first wafer on each module can consist of two parts: ex-situ heated slurry conditioning (before head touch-down) and heated slurry polishing (after head touch-down). During the heated slurry ex-situ conditioning period, the slurry can be heated from room temperature to the desired target temperature (ramping). Also the heated slurry can be distributed across the polishing pad by the conditioning recipe setup (priming). After the heated slurry is distributed evenly on the pad at the target temperature, the polish process may start. In another embodiment as described below in reference to FIG. 6, when a fault condition such as a problem with the polishing of a wafer occurs, the system may be restarted where the CMP apparatus is cooled down to room temperature and the process utilized for the initial wafer processing may be utilized to preheat the system for continued wafer processing.

It should also be appreciated that the system 100 may be used as a standalone device or the system 100 may be part of a larger system with other CMP or wafer processing devices. One exemplary embodiment of the larger system with multiple modular CMP devices is discussed in reference below to FIG. 4.

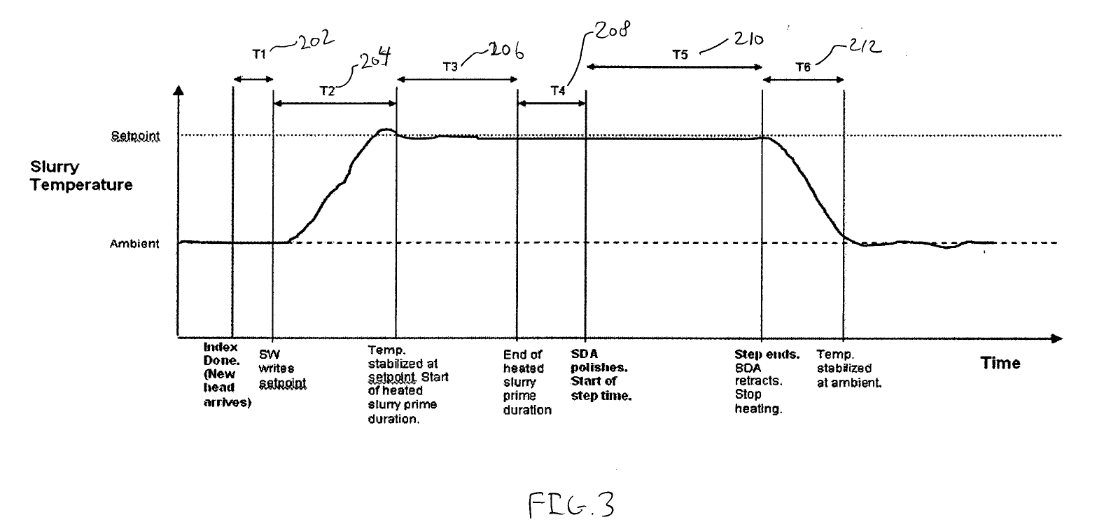

FIG. 3 shows a timeline illustrating the slurry heat processes for the processing of an initial wafer at start-up or restart in accordance with one embodiment of the present invention. It should be appreciated that the timeline presented in FIG. 3 is purely exemplary in nature and only one of the many different time progressions that may be utilized to heat the slurry and apply the preheated slurry to a wafer to preheat a CMP system. In addition, this exemplary timeline is described as when used with a modular CMP system such as those made by Lam Research Corporation in Fremont, Calif. When other types of CMP systems are utilized, the timeline may be different. In one embodiment, the timeline graph has the slurry temperature as the y-axis with time as the x-axis. Therefore, the timeline graph tracks the slurry temperature as it is heated for the initial wafer processing. It should be appreciated that T₁ through T₆ may be varied in any suitable way as long as the preheated slurry has been suitably applied to the polishing pad to ensure a desired polishing rate. In one embodiment, the first time period T₁-202 is a software delay in terms of ms that occurs after a new polishing head with a wafer arrives at a belt polishing module (such as, for example, the left belt polishing module and the right belt polishing module as described in reference to FIG. 4). The ambient temperature may be a starting state temperature and a set point temperature is a slurry temperature desired for a particular polishing operation. The set point temperature of the slurry may be varied depending on the polishing rate desired. The second time period T₂-204 is a temperature stabilization time that occurs before the temperature reaches the setpoint temperature. In other words, T₂-204 is the timeframe where the temperature of the slurry ramps up to a setpoint temperature. In one embodiment of T₂, the slurry is heated and applied to the polishing pad which, in one embodiment is being rotated. At this point, the polishing head has not been engaged and polishing is still not taking place. The third time period T₃-206 is a programmable heated slurry prime duration. During T₃-206, an ex-situ pre-conditioning is executed according to a desired configuration. In one embodiment T₃-206 is a time period that may be set by a user depending on the CMP operation desired to be run. During this time, the heated slurry is still being applied to the polishing pad and polishing is still not taking place. In one embodiment, a polishing pad conditioner may be activated to make sure that the slurry is evenly applied to the polishing pad. It should be appreciated that T₃ (also known as the priming time) can be varied to make sure that the preheated slurry has been evenly distributed on the polishing pad. The fourth time period T₄-208 is the time it for an SDA to engage. In one embodiment, this may take a matter of seconds. The fifth time period T₅-210 is the period where the spindle drive assembly (SDA) applies downward force and presses the wafer down on the moving polishing pad to polish the wafer to completion. In one embodiment, the SDA is a portion of the system (as described in reference to FIG. 2) that includes the carrier head that can be engaged by an assembly (not shown) that produces downward force on the wafer. The sixth time period T₆-212 is a time period where the polishing has concluded and the heat being applied to the slurry is turned off. At this point, the slurry being applied to the polishing returns to an ambient temperature (room temperature or the fabrication room temperature).

FIG. 4 illustrates a modular CMP system 300 in accordance with one embodiment of the present invention. In one embodiment, the modular CMP system 300 may include a front end loader 301 that is capable of loading unprocessed wafers into a head load module 302 and receiving processed wafers from the head load module 302. A wafer may be loaded into an indexer 310 which includes polishing heads that can hold the wafer during wafer polishing. The indexer 310 may also be configured to rotate at differing angles and at different directions to transport the wafer from one module to another. In one embodiment, the system 300 includes a right belt polish module (RBPM) that may receive the wafer loaded into the head load module by the indexer 310 rotating 90 degrees in a counter-clockwise direction 312. The polishing head containing the wafer can then engage with a downward force apparatus and the wafer may be pushed down onto a polishing pad for wafer polishing. The RBPM 304 may include a wafer polishing apparatus such as, for example, the CMP system 100 as discussed in reference to FIG. 2 to polish the wafer. The system 300 may also include a left belt polish module (LBPM) 306. The LBPM 306 may receive the wafer that has already been processed by the RBPM 304. This can occur after the polishing head has disengaged from the downward force device in the RBPM 306 and the indexer 310 has rotated 90 degrees thereby bringing the wafer into the LBPM 306 to be processed. In one embodiment, the LBPM 306 may include a wafer polishing apparatus such as, for example, the CMP system 100 as discussed in reference to FIG. 2 to polish the wafer. The system 300 may also include a rotary buff module that can further process the wafer after the polishing in the RBPM 304 and the LBPM 306 have been completed. Then the indexer can move another 90 degrees and unload the wafer out to the front end 301. It should be understood that the system 300 is only exemplary in nature and that the methods and apparatuses described herein may be utilized in any suitable type of CMP device and/or system with any suitable number and types of CMP or wafer processing devices.

FIG. 5 is a flowchart 400 defining a method for preheating the CMP system 100 in accordance with one embodiment of the present invention. It should be understood that the processes depicted in the flowcharts described herein may be in a program instruction form written on any type of computer readable media. For instance, the program instructions can be in the form of software code developed using any suitable type of programming language. In one embodiment the method begins with operation 402 where a slurry temperature is set. In one embodiment, of operation 402, a desired slurry temperature may be set in the GUI 119 and/or the heater control 117. After operation 402, the method moves to operation 404 where the slurry is heated to the set slurry temperature. Therefore, in one embodiment, the slurry is heated to the temperature that was set in operation 402. After operation 404, the method proceeds to operation 405 which applies the heated slurry to the polishing pad. In one embodiment, the heated slurry is applied to the polishing pad in a way such that even distribution of the slurry on the polishing pad occurs. In another embodiment, the heated slurry is applied to the polishing pad and a pad conditioner may evenly distribute the heated slurry on the polishing pad. Then operation 406 optionally distributes the heated slurry evenly on the polishing pad. After operation 405 or operation 406 (if the optional operation is conducted), the method advances to operation 407 which polishes the initial wafer using the polishing pad with the heated slurry. After operation 407, the method advances to operation 408 which stops heating the slurry for polishing of subsequent wafers. In operation 408, the heating of the slurry is terminated and room temperature slurry can then be used to process subsequent wafers.

FIG. 6 illustrates a flowchart 450 defining a method of preheating the CMP system 100 when an irregularity occurs in the polishing operation in accordance with one embodiment of the present invention. The flowchart 450 describes the method utilized when an irregularity is detected in the operation and the polishing is stopped, cooled down, and restarted using the method described in flowchart 400 (as described in further detail in reference to FIG. 5). An irregularity may be any event or status that could stop the wafer polishing such as, for example, slurry flow exceeding its upper limit, etc. The method begins with operation 452 which monitors polishing operation. In this embodiment, a software system may monitor the progression and effectiveness of the wafer polishing. After operation 452, the method advances to operation 454 where polishing of the wafer is stopped when irregularity is detected in the polishing. Then operation 456 resets the chemical mechanical planarization system to the original system temperature. After operation 456, the method moves to operation 404 of the flowchart 400 as described in reference to FIG. 5. Then the method completes operations 404, 405, 406 (optionally), 407, and 408.

Exemplary actions with irregularities which may cause stoppage in wafer polishing are described in Table 1 below:

TABLE 1

| Scenarios | Actions |
|---|---|
| Process from wet-idle | Both modules should start with heated slurry on the 1st wafer |
| state | |
| Alarm happens when | Mark 1st wafer for re-work, index and start rinsing both |
| one wafer on RBPM, | modules and use the 1st wafer work on LRBM with heated |
| no wafer on LBPM | slurry on both modules |
| Alarm happens when | Mark the last wafer for re-work and skip subsequent polish on |
| one wafer on LBPM, | LBPM. Start rinsing both modules |
| no wafer on RBPM | |
| Alarm happens on | Mark the alarmed wafer for re-work, and start rinsing RBPM |
| RBPM while another | for wet-idle recovery. Continue to polish the LRPM until it |
| wafer on LBPM | finishes and then rinse the LRPM. When resume the process, |
| | use the alarmed wafer for the LRPM under heated slurry. |
| Alarm happens on | Mark the alarmed wafer for re-work on LBPM and rinse the |
| LRPM while another | LBPM. Continue polishing wafer on RBPM until it finishes |
| wafer on RBPM | and then rinse the RBPM. When resume the process, index and |
| | use the coming wafer for the RBPM and LRPM under heated |
| | slurry. |
| PAUSE/RESUME a | Mark the wafers on polishing and continue to finish the wafers |
| process | on both modules. Then rinse everything. Use the existing wafer |
| | to continue processes with heated slurry on both modules |
| Alarm happens during | Stop the current process and start rinsing everything. When |
| the ramp period (T2) | resume the process, use the existing wafer to continue the |
| for the 1st wafer under | process with heated slurry. |
| heated slurry | |
| Alarm happens during | Stop the current process and start rinsing everything. When |
| the slurry priming | resume the process, use the existing wafer to continue the |
| period (T3) for the 1st | process with heated slurry |
| wafer under heated | |
| slurry | |
| Alarm happens during | Stop the current process and start rinsing everything. When |
| the after slurry priming | resume the process, use the existing wafer to continue the |
| period but before SDA | process with heated slurry |
| down (T4) for the 1st | |
| wafer under heated | |
| slurry | |

It should be appreciated that the irregularities that may cause the stoppage of the wafer polishing is only one embodiment out of many possible embodiments and that the methodology and apparatus described herein may be used to restart nearly any cessation of wafer polishing. A first scenario where the CMP system 100 may be preheated is where the wafer is polished from a wet-idle start. The wet-idle start is the polishing of a first wafer. A second scenario where the CMP system 100 may be preheated occurs when wafer polishing is restarted after an alarm stops wafer polishing that was already occurring. Exemplary alarm situations are listed in the second through ninth rows of Table 1. In one embodiment, when the CMP system 100 is restarted after an alarm, the system 100 (or as described in Table 1 one or both of the LBPM and RBPM) can be rinsed with deionized water (DIW) or any other suitable cooling liquid to reduce the temperature of the system to the ambient temperature of the fabrication environment.

The invention has been described herein in terms of several exemplary embodiments. Other embodiments of the invention will be apparent to those skilled in the art from consideration of the specification and practice of the invention. The embodiments and preferred features described above should be considered exemplary, with the invention being defined by the appended claims.

What is claimed is:

1. A method for processing a wafer using a chemical mechanical planarization (CMP) apparatus, comprising:
(a) providing a wafer to be processed;
(b) heating a slurry to be applied to a polishing pad of the CMP apparatus;
(c) applying a heated slurry to the polishing pad;
(d) polishing the wafer using the heated slurry; and
(e) stopping the heating of the slurry for a subsequent wafer to be processed.

2. A method for processing a wafer using a chemical mechanical planarization (CMP) apparatus as recited in claim 1, wherein the slurry is heated to a temperature between about 70 F. and about 110 F. and the temperature is above an ambient temperature.

3. A method for processing a wafer using a chemical mechanical planarization (CMP) apparatus as recited in claim 1, wherein a polishing rate of the wafer is at a substantially steady state from the beginning of the polishing.

4. A method for processing a wafer using a chemical mechanical planarization (CMP) apparatus as recited in claim 1, further comprising:
lowering a temperature of the CMP apparatus to a starting state temperature after a polishing stoppage;
repeating operations (a)-(e).

5. A method for processing a wafer using a chemical mechanical planarization (CMP) apparatus as recited in claim 4, wherein the polishing stoppage results from a polishing irregularity.

6. A method for processing a wafer using a chemical mechanical planarization (CMP) apparatus as recited in claim 4, wherein the lowering of the temperature of the CMP apparatus to the starting state temperature includes rinsing the CMP apparatus with a fluid.

7. A method for processing a wafer using a chemical mechanical planarization (CMP) apparatus as recited in claim 6, wherein the fluid is deionized water.

8. A method for processing a wafer using a chemical mechanical planarization (CMP) apparatus as recited in claim 1, wherein the wafer is an initial wafer in a multiple wafer processing operation.

9. A method for processing a wafer using a chemical mechanical planarization (CMP) apparatus as recited in claim 1, wherein the slurry is heated to a temperature corresponding to a set point temperature of the polishing operation.

10. A method for processing a wafer using a chemical mechanical planarization (CMP) apparatus as recited in claim 1, wherein the stopping the heating includes turning off a slurry heater for a subsequent wafer polishing after the polishing of the wafer has been completed.

11. A method for processing a wafer using a chemical mechanical planarization (CMP) apparatus as recited in claim 1, further comprising:
distributing the heated slurry evenly on the polishing pad after operation (c) and before operation (d).

12. A method for processing a wafer using a chemical mechanical planarization (CMP) apparatus, comprising:
(a) providing a wafer to be processed;
(b) heating a slurry to be applied to a polishing pad of the CMP apparatus to a temperature between 70 F. and 100 F.;
(c) applying the heated slurry to the polishing pad;
(d) distributing the heated slurry evenly on the polishing pad;
(e) polishing the wafer using the heated slurry;
(f) stopping the heating of the slurry for a subsequent wafer processing; and
(g) when a polishing irregularity occurs;
stopping the polishing,
lowering a CMP apparatus temperature to a starting state temperature,
repeating operations (a) through (f).

13. A method for processing a wafer using a chemical mechanical planarization (CMP) apparatus as recited in claim 12, wherein the temperature between 70 F. and 100 F. is above an ambient temperature.

14. A method for processing a wafer using a chemical mechanical planarization (CMP) apparatus as recited in claim 12, wherein the polishing stoppage results from a polishing irregularity.

15. A method for processing a wafer using a chemical mechanical planarization (CMP) apparatus as recited in claim 12, wherein the lowering of the temperature of the CMP apparatus to the starting state includes rinsing the CMP apparatus with a fluid.

16. A method for processing a wafer using a chemical mechanical planarization (CMP) apparatus as recited in claim 15, wherein the fluid is deionized water.

17. A method for processing a wafer using a chemical mechanical planarization (CMP) apparatus as recited in claim 12, wherein the wafer is an initial wafer in a multiple wafer processing operation.

18. A method for processing a wafer using a chemical mechanical planarization (CMP) apparatus as recited in claim 12, wherein the slurry is heated to a temperature corresponding to a set point temperature of the polishing operation.

19. A computer readable medium including program instructions for implementing a method for processing a wafer using a chemical mechanical planarization (CMP) apparatus, the computer readable medium comprising:
(a) program instructions for providing a wafer to be processed;
(b) program instructions for heating a slurry to be applied to a polishing pad of the CMP apparatus;
(c) program instructions for applying the heated slurry to the polishing pad;
(d) program instructions for polishing the wafer using the heated slurry; and
(e) program instructions for stopping the heating of the slurry for a subsequent wafer processing.

20. A computer readable medium as recited in claim 19, wherein the slurry is heated to a temperature between about 70 F. and 110 F.

21. A computer medium as recited in claim 19, further comprising:
program instructions for lowering a temperature of the CMP apparatus to a starting state after a polishing stoppage;
program instructions for repeating program instructions (a)-(e).

22. A computer medium as recited in claim 19, further comprising:
program instructions for distributing the heated slurry evenly on the polishing pad after operation (c) and before operation (d).
